(19) United States
(12) Patent Application Publication
(10) Pub. No.: US 2026/0203458 A1
(43) Pub. Date: Jul. 16, 2026

(54) Transforming Gauging Reports to Models

(71) Applicant: American Bureau of Shipping, Spring, TX (US)

(72) Inventors: Amba Sachidanandam, The Woodlands, TX (US); Nathaniel Terre, Houston, TX (US); Sameer Kalghatgi, Houston, TX (US)

(21) Appl. No.: 19/134,091

(22) PCT Filed: Jan. 27, 2024
(86) PCT No.: PCT/US2024/013256

§ 371 Date: May 29, 2025

Related U.S. Application Data
(60) Provisional application No. 63/481,927, filed on Jan. 27, 2023.

(51) Int. Cl. G06F 30/15

(52) U.S. Cl. CPC G06F 30/15

(57) ABSTRACT

In one embodiment, a method includes providing a vessel definition, receiving a gauging report comprising a plurality of plate thicknesses of the vessel and sketches showing locations of the plurality of plate thicknesses, extracting plate thicknesses from the gauging report, connecting the sketches to one or more of the plate thicknesses, identifying locations in the vessel definition for one or more of the plate thicknesses, and correlating one or more of the plate thicknesses to a vessel model.

### CROSS-REFERENCE TO RELATED APPLICATION

This application claims the benefit under 35 U.S.C. § 119(e) of U.S. Provisional Patent Application No. 63/481927, filed 27 Jan. 2023, which is incorporated herein by reference

### TECHNICAL FIELD

This disclosure relates to vessel analysis and modeling.

### BACKGROUND

Current gauging reports may be provided by vendors in a format promulgated by the International Association of Classification Societies (IACS). For a commercial vessel, the gauging reports may be a large portable document format (PDF) files of hundreds of pages that contain tables with plate thickness measured at various points on a ship or marine structure. Existing gauging reports may include sketches that show the approximate location where these measurements were taken. An asset owner and Class surveyor then may interpret these results and discuss the results and plan for any needed repairs.

### SUMMARY

In particular embodiments, a modeling method may include an approach for vessel analysis and modeling. The method may provide a vessel definition and receive a gauging report comprising a plurality of plate thicknesses of the vessel and sketches showing locations of the plurality of plate thicknesses in a survey. The method may further extract the plurality of plate thicknesses from the gauging report. The method may further connect the sketches to one or more of the plate thicknesses. The method may further identify locations in the vessel definition for one or more of the plate thicknesses. The method may further correlate one or more of the plate thicknesses to a vessel model. The method may further use a digital twin and a three-dimensional model to generate a virtual vessel model using the plurality of plate thickness and the sketches. The method may further use the virtual vessel model to determine a structure response for the vessel. The method may further use the virtual vessel model and the structural response to determine a task to apply a remedial operation.

In particular embodiments, the vessel definition determines a vessel and a plurality of vessel components, the plurality of vessel components including hull parts based on existing data. The existing data includes one or more main structural elements based on classification data and drawings. Boundaries of the one or more main structural elements form a frame, deck, side shells, or other hull parts for use. The boundaries of the one or more main structural elements are determined with or without a three-dimensional (3D) compartment model or a 3D structural model, the 3D compartment model or 3D structural model including a plurality of plate definitions and/or boundaries. The sketches are computer-aided design (CAD) generated.

In particular embodiments, the modeling method may perform optical character recognition of the survey in the gauging report to extract usable data, the gauging report including a plurality of tables of thicknesses and sketches in portable document format (PDF) files. The modeling method may adjust the virtual vessel definition as the gauging report is read by correlating plate identifiers to plates, compartments and bulkheads definitions. The modeling method may apply a supervised or unsupervised machine learning and other heuristics including virtual vessel data to connect every measurement with an associated sketch. The modeling method may apply one or more image processing and image recognition algorithms to identify the locations of gauge points from the sketches in the survey.

In particular embodiments, the modeling method determine, for each sketch, an origin and a scale using sketch boundaries and the largest linear dimensions from the gauging report. The modeling method may determine, for each sketch, a respective scaled sketch by converting the locations from paper scale to ship/vessel scale based on the origin and the scale. The modeling method may orient, for each sketch, the respective scaled sketch based on various identifiers in the corresponding sketch and existing vessel data using heuristic methods. The modeling method may apply, for each sketch, one or more correlation techniques to map a point in the scaled sketch to a corresponding location on the vessel using the vessel model.

In particular embodiments, the modeling method may determine a structural response to a real-time event by performing physics-based analysis on the one or more plate thicknesses on one or more 3D models. the modeling method may determine an error resistant modification of plate thickness based on estimated corrosion rates for plates that are not gauged and determination of such rates from gauged points and their locations on the vessel. The modeling method may calculate remaining useful life and estimating corrosion on other vessels by correlating the estimated corrosion rates and historic trends to vessels operation.

In particular embodiments, a modeling method may include an approach for vessel analysis and modeling. The method may provide a vessel definition and receive a gauging report comprising a plurality of plate thicknesses of the vessel and sketches showing locations of the plurality of plate thicknesses in a survey. The method may further extract the plurality of plate thicknesses from the gauging report and connect the sketches to one or more of the plate thicknesses.

In particular embodiments, a modeling method may include an approach for vessel analysis and modeling. The method may provide a vessel definition and receive a gauging report comprising a plurality of plate thicknesses associated with several structural members. The method may further identify locations in the vessel definition for one or more of the structural members in a survey. The method may further correlate one or more of the plate thicknesses to a vessel model.

### BRIEF DESCRIPTION OF THE DRAWINGS

The present invention is illustrated by way of example and not limitation with reference to the accompanying figures, in which like references generally indicate similar elements or features.

FIG. 1 illustrates a vessel transforming system for transforming a gauging report to a virtual vessel model.

FIG. 2 illustrates a method for applying one or more machine learning models to connect a plurality of plate thicknesses with an associated sketch.

FIG. 3 illustrates a flow chart of one example method of transforming gauging reports to vessel.

FIG. 4 illustrates an example vessel modeling system.

### DETAILED DESCRIPTION

The present disclosure is directed to methods, systems, and apparatuses to read, interpret, and convert gauging reports that consist of a sketch and a tabular list of values into a three-dimensional (3D) model for easy visualization and ensure key areas in need of repair are easily identified. A gauging report includes one or more tables with plate thickness measured at various points on a ship or marine structure. Gauging reports may include sketches that show the approximate location where these measurements were taken. These sketches may be computer-aided design (CAD) generated.

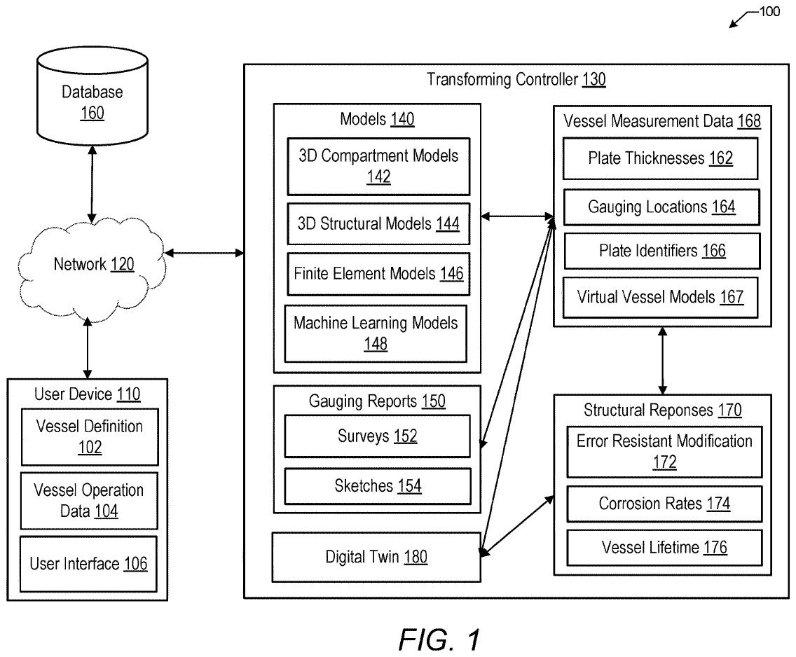

FIG. 1 illustrates a vessel transforming system 100 for transforming a gauging report to a virtual vessel model. In an embodiment, vessel transforming system 100 may include user device 110, network 120, transforming controller 130, and database 160. User device 110 may be communicatively coupled to transforming controller 130 and database 160. Thus, a user may use user device 110 via user interface 106 to send a request to transforming controller 130 to obtain a gauging report 150 and vessel definition 102 and transform the gauging report 150 to a virtual vessel model 167 based on vessel definition 102 provided by the user. For example, gauging report 150 may include a plurality of plate thicknesses 162 of the vessel and one or more sketches 154 showing a plurality of gauging locations 164 of the plurality of plate thicknesses 162 in a survey 152. As another example, gauging report 150 may be stored in database 160. In particular, transforming controller 130 may be configured to determine one or more vessel measurement data 168 by extracting the plurality of plate thicknesses 162 from gauging report 150 and connect the one or more sketches 154 to the plurality of plate thicknesses 162.

In an embodiment, user device 110 may be communicatively coupled to network 120 to use transforming controller 130 to determine the one or more vessel measurement data 168, such as plate thicknesses 162, gauging locations 164, plate identifiers 166, and virtual vessel models 167. User device 110 may be configured to receive vessel definition 102 and vessel operation data 104 from the user. For example, vessel definition 102 may define a vessel and its components, including hull parts based on existing data. In particular, the existing data may be based on classification data and drawings. As another example, vessel operation data 104 may include historic trends to vessels operation associated with vessel definition 102. Network 120 broadly represents any wireline or wireless network, using any of satellite or terrestrial network links, such as public or private cloud on the Internet, local area networks (LANs), metropolitan area networks (MANs), wide area networks (WANs), a public switched telephone network (PSTN), campus network, internetworks, or combinations thereof. The network 120 may include or comprise the public internet and networked server computers that implement Web2 and/or Web3 technologies. Network 120 may comprise or support intranets, extranets, or virtual private networks (VPNs). Network 120 may also comprise a public switched telephone network (PSTN) using digital switches and call forwarding gear. Network 120 may also comprise a public switched telephone network (PSTN) using digital switches and call forwarding gear.

In an embodiment, transforming controller 130 may be configured to perform optical character recognition of the survey 152 in gauging report 150 to extract usable data, such as plate thickness 162 and gauging locations 164. For example, transforming controller 130 may be configured to receive a gauging report 150 in a PDF file with tables of a plurality of plate thicknesses 162 and the one or more sketches 154 for survey 152. Transforming controller 130 may perform optical character recognition of survey 152 to extract usable data by correlating a plurality of plate identifiers 166 to plates, compartments and bulkheads definitions and adjust the virtual vessel definition 102 as the document is being read.

In an embodiment, transforming controller 130 may be configured to connect the one or more sketches 154 to frames from the virtual vessel definition 102. In example embodiments, transforming controller 130 may be configured to connect the one or more sketches 154 from the survey 152 showing where measurements were taken to the tables to corresponding tabular data in database 160. In some embodiments, the one or more sketches 154 may not be labelled with the right frame. Transforming controller 130 may be configured to apply a machine learning model 148, such as a supervised machine learning model, an unsupervised machine learning model, and/or a heuristics model, to classify virtual vessel data, such as vessel measurement data 168, to connect every measurement with an associated sketch.

In an embodiment, transforming controller 130 may be configured to identify the plurality of gauging locations 164 from the one or more sketches 154 in survey 152. In example embodiments, other data from sketch 154 including a plurality of plate identifiers 166 and gauging locations 164 may be extracted for correlation with tabular and existing virtual vessel data. Transforming controller 130 may be configured to process the one or more sketches 154 in survey 152 through one or more image processing and image recognition algorithms to identify locations of gauge points from the one or more sketches 154 in survey 152. For example, transforming controller 130 may be configured to scale gauging locations 164 in gauging reports 150 based on sketch boundaries and the largest linear dimensions in the one or more sketches 154. The scales in different survey sketches 152 may vary from each other or from the scale in different virtual vessel models 167. As another example, transforming controller 130 may be configured to correlate the frame from survey 152 to a vessel model 167 by mapping one or more points in each frame (sketch) to one or more appropriate location on the vessel using virtual vessel model 167.

In an embodiment, transforming controller 130 may be configured to generate a digital twin 180 based on the structure of the vessel using virtual vessel data 168. In particular, transforming controller 130 may be configured to apply measured plate thicknesses 162 on one or more models 140, such as a 3D compartment model 142, a 3D structural model 144, and/or a finite element model 146, and perform physics-based analysis to provide one or more structural responses 170 to events in real-time. For example, transforming controller 130 may be configured to use digital twin 180 to determine a corrosion rate 174 associated with a gauging point 164 based on a virtual vessel model 167. As another example, transforming controller 130 may be configured to use digital twin 180 to determine an error resistant modification 172 of plate thickness 162 based on estimated corrosion rates 174 for plates that are not gauged and determination of such rates from gauged points and their locations 164 on the vessel. As another example, transforming controller 130 may be configured to use digital twin 180 to analyze corrosion rate 174 and historic trends by correlating to vessel operation data 104 to calculate remaining useful life 176 and to estimate corrosion on other vessels.

Although FIG. 1 describes and illustrates particular components, devices, or systems carrying out particular actions, this disclosure contemplates any suitable combination of any suitable components, devices, or systems carrying out any suitable actions. For example, transforming controller 130 may perform one or more requests from user device 110.

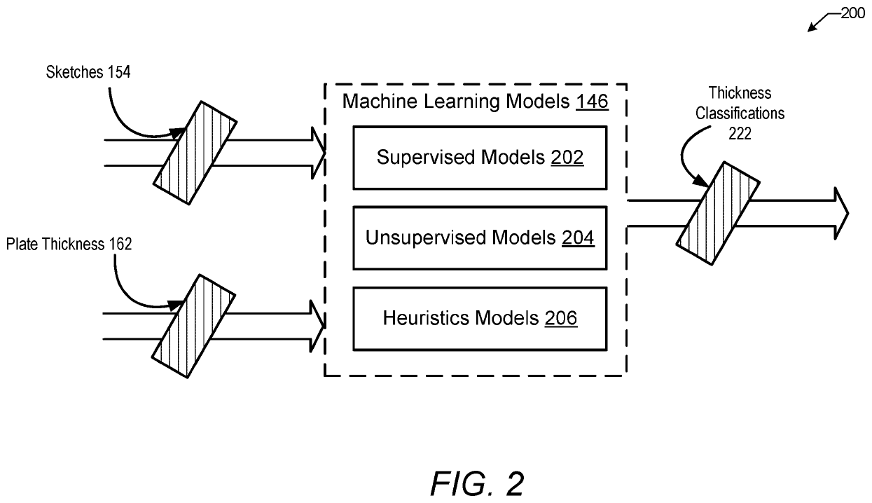

FIG. 2 illustrates a method 200 for applying one or more machine learning models 146 to connect a plurality of plate thicknesses 162 with an associated sketch 154. In particular, the one or more machine learning models 146 may include a supervised model 202, an unsupervised model 204, or a heuristics model 206. In particular, the one or more machine learning models 146 may use a plurality of plate thickness 162 and sketches 154 as input to determine a classification, such as thickness classifications 222, for each of the plurality of plate thickness 162 by correlating the plurality of plate thickness 162 with a corresponding sketch 154.

In an embodiment, supervised model 202 may be a tree-like model training using a supervised machine learning algorithm, such as decision tree based algorithm. Supervised model 202 may be trained use a decision tree algorithm to classify one or more subjects into a map of possible outcomes of multiple related choices in which each internal node represents a test on an attribute, each branch represents an outcome of the test, and each leaf node represents a class label. A path from root to leaf is determined based on a decision tree classification rule. In particular, a decision tree typically starts with a single node, which branches into possible outcomes. Each of those outcomes leads to additional nodes, which branch off into other possible outcomes. The accuracy of a decision tree model is controlled by a depth and a node splitting function of the decision tree model at the cost of increasing computation time. A decision tree model may be evaluated using one or more metrics, such as accuracy, sensitivity, specificity, precision, miss rate, false discovery rate, and false omission rate, etc., using the measurements classified by the decision tree model.

Furthermore, supervised model 202 may be training using a random forest algorithm to determine a random forest model consisting of multiple decision trees. A decision tree model is a block of a random forest model and multiple decision tree models are combined to make a random forest model. For example, each individual tree in the random forest model splits out a class prediction and the class with the most votes becomes our model's winning prediction. Compared to a decision tree algorithm, a random forest tree uses a large number of relatively uncorrelated decision tree models to operate as a committee to determine a winner class which usually outperforms any of individual constituent decision tree models.

In an embodiment, unsupervised model 204 may be a clustering model trained using an unsupervised machine learning algorithm, such as k-means. The k-means algorithm may start with k random cluster center points and then solve the optimization problem by minimizing an objective function by assigning data points to the nearest cluster center. Once this assignment is done, the k-means algorithm recomputes the cluster center. This process continues until there is not much change in the cluster assignment. As a result, the clustering model may be applied to determine the plurality of plate thickness clustering. In an embodiment, heuristics model 206 may be used to read the plurality of plate thicknesses 162 and sketches 154 and correlate each of the plurality of plate thicknesses 162 to a corresponding sketch 154 based on a predetermined criterion from prior experience or user input.

Although FIG. 2 describes and illustrates particular components, devices, or systems carrying out particular actions, this disclosure contemplates any suitable combination of any suitable components, devices, or systems carrying out any suitable actions. For example, the one or more machine learning models 146 may classify one or more vessel measurement data 168 (referring to FIG. 1).

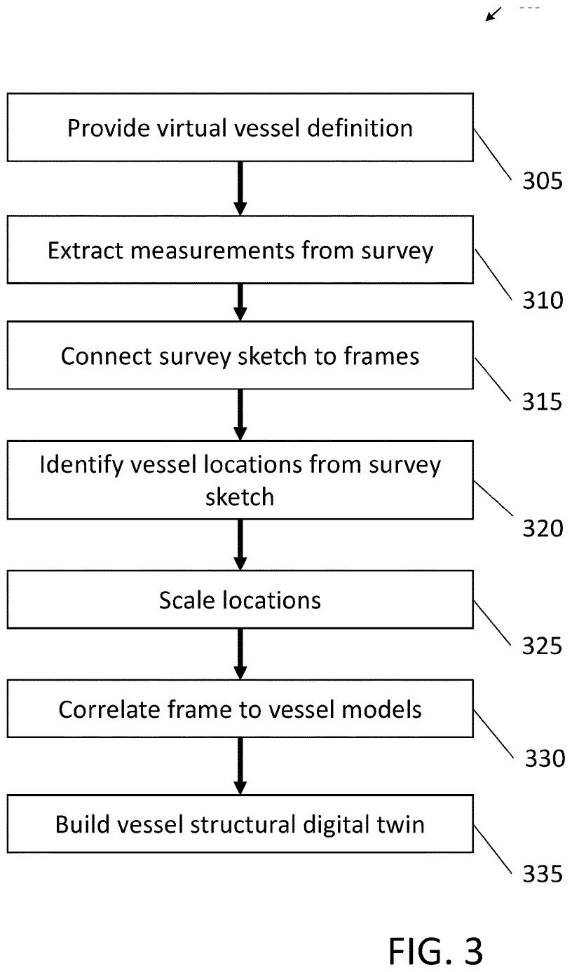

FIG. 3 is a flow chart of one example method 300 of transforming gauging reports to vessel models. Method 100 of FIG. 3 starts at step 305, where a virtual vessel definition is provided. The system may define a vessel and its components, including hull parts based on existing data. In certain example embodiments, the existing data may be based on classification data and drawings. In example embodiments, the data may include one or more main structural elements. In some embodiments, the boundaries of those elements may be defined with or without an available 3D compartment model or 3D structural model. The boundaries of these elements may form a frame, deck, side shells, or other hull parts for use in the process towards building a visual digital twin. In some embodiments, a 3D compartment model or a structural 3D model may include a plurality of plate definitions and/or boundaries. This may include building a visual digital twin, but is not a pre-requisite for the process.

In some embodiments, a 3D Computer-aided design (CAD) model of the vessel or a unit of the vessel may be used to generate a gauging plan. The gauging plan may be extracted into a spreadsheet including a plurality of geo-cordinates of multiple gauge points associated with the 3D CAD model. Likewise, the actual thicknesses may be entered into the spreadsheet. Thus, the information data in the spreadsheet may be imported into a 3D vessel model which include thicknesses associated with the 3D model structural elements.

At step 310, the system may extract the thickness measurements from the survey. In example embodiments the system may receive a PDF file with tables of thicknesses and sketches. The system may perform optical character recognition of the survey to extract usable data. In example embodiments, the system may correlate plate identifiers to plates, compartments and bulkheads definitions and adjust the virtual vessel definition as the document is being read.

At step 315, the system may connect survey sketches to frames from the virtual vessel definition. In example embodiments, the system may connect sketches from the survey showing where measurements were taken to the tables to corresponding tabular data in the database. In some embodiments, the sketches may not be labelled with the right frame. The system may use supervised or unsupervised machine learning and other heuristics including virtual vessel data to connect every measurement with an associated sketch.

At step 320, the system may identify gauging location from survey sketches in the survey. In example embodiments, other data from the sketch including plate identifiers and plate locations may be extracted for correlation with tabular and existing virtual vessel data. The system may process the survey sketch through one or more image processing and image recognition algorithms to identify locations of gauge points from the sketches in the survey

At step 325, the system may scale the locations from the survey report. In example implementations, the scales in different survey sketches may vary from each other or from the scale in vessel models. In example implementations, the system may convert locations from paper scale to ship/vessel scale. For example, the system may use sketch boundaries and the largest linear dimensions to determine origin and scale of each sketch.

At step 330, after any scaling, the system may correlate the frame from the survey to the vessel models. In example implementations, the system may orient the scaled sketches based on various identifiers in the sketch and existing vessel data using heuristic methods. The system may also display points and the amount of diminution on one or more of existing compartment models, 3D structural models, and finite element models. For example, the system may use correlation techniques to map points in each frame (sketch) to the appropriate location on the vessel using the virtual vessel model.

At step 335, the system may build a vessel structural digital twin. In example implementations, the system may apply measured thicknesses on 3D models and perform physics-based analysis to provide one or more structural responses to events in real-time. For example, the system may make an error resistant modification of plate thickness based on estimated corrosion rates for plates that are not gauged and determination of such rates from gauged points and their locations on the vessel. The corrosion rates and historic trends may be correlated to vessels operation to calculate remaining useful life and to estimate corrosion on other vessels.

In some embodiments, the corrosion rates associated with a plurality of structural elements are correlated and influenced by many factors not limited to sea water salinity, cargo fluid corrosivity, structural stress and strain, mechanical impact (e.g., contact, abrasion, erosion, damage), presence of dissimilar chemistry in base material and weld material, fabrication processes (e.g., preheat, annealing, blasting, coating specifications, coating procedures, etc.). The corrosion rates determined by measuring the actual thicknesses (gauging) of the structural elements at different intervals allow extrapolation of the future predicted condition based on a simple linear or quadratic extrapolation. This enables estimation of remaining useful life based on the corrosion rates associated with the plurality of structural elements.

Furthermore, the system may generate one or more tasks associated with the one or more structural responses to a user via a user device, such as user device 110 (referring to FIG. 1). For example, the system may generate one or more tasks to repair or replace a component of a vessel based on an error resistant modification determined from the digital twin. As another example, the system may generate one or more tasks to apply a coating surface to a component of a vessel to prevent the vessel from corrosion and increase vessel lifetime.

The above described tasks may be generated, for instance, using one or more processing algorithms implemented as software in one or more of the vessel transforming system 100 (referring to FIG. 1), and may be represented as a separate data structure or as data structures associated with a particular request from a user. In certain embodiments, transforming controller 130 (referring to FIG. 1) may generate the tasks based, at least in part, on a request received from user device 110 (referring to FIG. 1), communicate the tasks to user device 110 (referring to FIG. 1). In certain embodiments, at least some of the tasks may be triggered by a user communication received at one or more of user device 110 (referring to FIG. 1)

In some embodiments, the vessel transforming system 100 (referring to FIG. 1) may integrate the output results from the physics-based analysis to generate a 3D visualization of the structural elements which have been wasted (corroded beyond allowable limits) and/or substantially corroded (e.g., corroded to the extent of 75% or more of the permissible (allowable) wastage limit). Thus, the vessel transforming system 100 (referring to FIG. 1) may use the 3D visualization to perform repairs and make assessments. In the absence of the visualization of the structural elements, traditional method is to visualize the structural elements to repair based on available sketches and tables. The 3D visualization may improve the assessment of integrity and enable better planning to perform repairs. As a result, repairs may be either to replace structural elements as per original completely or partially or arrest the corrosion by coating or other methods to protect structural elements (e.g., in case of steel, it may be cathodic protection). The 3D visualization may be outputted on a screen and used to print output along with details of the affected structural elements and remaining life based on a corrosion rate.

The methods, systems, and apparatuses of the present disclosure may provide one or more benefits over prior systems. First, the methods, systems, and apparatuses of the present disclosure may provide faster interpretation of areas that need attention on a vessel. Second, the methods, systems, and apparatuses of the present disclosure may provide for quick identification and resolution of any errors or omissions during gauging campaigns. Third, the methods, systems, and apparatuses of the present disclosure may provide faster physics-based analysis using one or more of visualization or building a visual digital twin. Fourth, the methods, systems, and apparatuses of the present disclosure may provide ways to respond to changes in corrosion rates across a fleet of vessels due to environmental factors faster by detecting smaller changes in trends. This, in turn, may help prioritize critical areas for repair to enhance safety and optimize cost.

Example embodiments may include one or more controllers, computers, or other data handling devices. In some embodiments, controllers may include one or more processor types. Processor may include, for example, a microprocessor, microcontroller, digital signal processor (DSP), application specific integrated circuit (ASIC), or any other digital or analog circuitry configured to interpret and/or execute program instructions and/or process data. In some embodiments, processor may be communicatively coupled to memory. Processor may be configured to interpret and/or execute non-transitory program instructions and/or data stored in memory. Program instructions or data may constitute portions of software for carrying out machine learning, optical character recognition and/or data analysis, as described herein. Memory may include any system, device, or apparatus configured to hold and/or house one or more memory modules; for example, memory may include read-only memory, random access memory, solid state memory, or disk-based memory. Each memory module may include any system, device or apparatus configured to retain program instructions and/or data for a period of time (e.g., computer-readable non-transitory media).

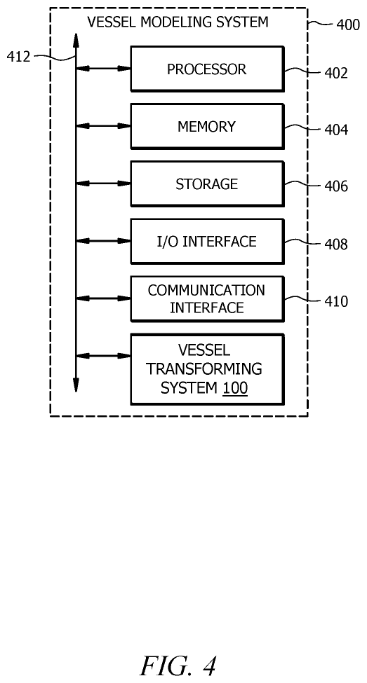

FIG. 4 illustrates an example vessel modeling system 400. In particular embodiments, one or more vessel modeling systems 400 perform one or more steps of one or more methods described or illustrated herein. In particular embodiments, one or more vessel modeling systems 400 provide functionality described or illustrated herein. In particular embodiments, software running on one or more vessel modeling systems 400 performs one or more steps of one or more methods described or illustrated herein or provides functionality described or illustrated herein. Particular embodiments include one or more portions of one or more vessel modeling systems 400. Herein, reference to an information handling system may encompass a computer or a computing device, and vice versa, where appropriate. Moreover, reference to an information handling system may encompass one or more computer systems, where appropriate. Further, the vessel transforming system 100 in FIG. 1 may be incorporated into the illustrated vessel modeling system 400. With reference to the present disclosure, vessel modeling system 400 may be the aforementioned product incorporating vessel transforming system 100, as described above with respect to FIG. 1. As such, “product” and “vessel modeling system 400” may herein be used interchangeably.

This disclosure contemplates any suitable number of vessel modeling systems 400. This disclosure contemplates vessel modeling system 400 taking any suitable physical form. As example and not by way of limitation, vessel modeling system 400 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, vessel modeling systems 400 may include one or more vessel modeling systems 400; be unitary or distributed; span multiple locations; span multiple machines; span multiple data centers; or reside in a cloud, which may include one or more cloud components in one or more networks. Where appropriate, one or more vessel modeling systems 400 may perform without substantial spatial or temporal limitation one or more steps of one or more methods described or illustrated herein. As an example and not by way of limitation, one or more vessel modeling systems 400 may perform in real time or in batch mode one or more steps of one or more methods described or illustrated herein. One or more vessel modeling systems 400 may perform at different times or at different locations one or more steps of one or more methods described or illustrated herein, where appropriate.

In particular embodiments, vessel modeling system 400 includes a processor 402, memory 404, storage 406, an input/output (I/O) interface 408, a communication interface 410, and a bus 412. Although this disclosure describes and illustrates a particular information handling system having a particular number of particular components in a particular arrangement, this disclosure contemplates any suitable information handling system having any suitable number of any suitable components in any suitable arrangement.

In particular embodiments, processor 402 includes hardware for executing instructions, such as those making up a computer program. As an example and not by way of limitation, to execute instructions, processor 402 may retrieve (or fetch) the instructions from an internal register, an internal cache, memory 404, or storage 406; decode and execute them; and then write one or more results to an internal register, an internal cache, memory 404, or storage 406. In particular embodiments, processor 402 may include one or more internal caches for data, instructions, or addresses. This disclosure contemplates processor 402 including any suitable number of any suitable internal caches, where appropriate. As an example and not by way of limitation, processor 402 may include one or more instruction caches, one or more data caches, and one or more translation lookaside buffers (TLBs). Instructions in the instruction caches may be copies of instructions in memory 404 or storage 406, and the instruction caches may speed up retrieval of those instructions by processor 402. Data in the data caches may be copies of data in memory 404 or storage 406 for instructions executing at processor 402 to operate on; the results of previous instructions executed at processor 402 for access by subsequent instructions executing at processor 402 or for writing to memory 404 or storage 406; or other suitable data. The data caches may speed up read or write operations by processor 402. The TLBs may speed up virtual-address translation for processor 402. In particular embodiments, processor 402 may include one or more internal registers for data, instructions, or addresses. This disclosure contemplates processor 402 including any suitable number of any suitable internal registers, where appropriate. Where appropriate, processor 402 may include one or more arithmetic logic units (ALUs); be a multi-core processor; or include one or more processors 402. Although this disclosure describes and illustrates a particular processor, this disclosure contemplates any suitable processor.

In particular embodiments, memory 404 includes main memory for storing instructions for processor 402 to execute or data for processor 402 to operate on. As an example and not by way of limitation, vessel modeling system 400 may load instructions from storage 406 or another source (such as, for example, another vessel modeling system 400) to memory 404. Processor 402 may then load the instructions from memory 404 to an internal register or internal cache. To execute the instructions, processor 402 may retrieve the instructions from the internal register or internal cache and decode them. During or after execution of the instructions, processor 402 may write one or more results (which may be intermediate or final results) to the internal register or internal cache. Processor 402 may then write one or more of those results to memory 404. In particular embodiments, processor 402 executes only instructions in one or more internal registers or internal caches or in memory 404 (as opposed to storage 406 or elsewhere) and operates only on data in one or more internal registers or internal caches or in memory 404 (as opposed to storage 406 or elsewhere). One or more memory buses (which may each include an address bus and a data bus) may couple processor 402 to memory 404. Bus 212 may include one or more memory buses, as described below. In particular embodiments, one or more memory management units (MMUs) reside between processor 402 and memory 404 and facilitate accesses to memory 404 requested by processor 402. In particular embodiments, memory 404 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 404 may include one or more memories 404, where appropriate. Although this disclosure describes and illustrates particular memory, this disclosure contemplates any suitable memory.

In particular embodiments, storage 406 includes mass storage for data or instructions. As an example and not by way of limitation, storage 406 may include a hard disk drive (HDD), a floppy disk drive, flash memory, an optical disc, a magneto-optical disc, magnetic tape, or a Universal Serial Bus (USB) drive or a combination of two or more of these. Storage 406 may include removable or non-removable (or fixed) media, where appropriate. Storage 406 may be internal or external to vessel modeling system 400, where appropriate. In particular embodiments, storage 406 is non-volatile, solid-state memory. In particular embodiments, storage 406 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 406 taking any suitable physical form. Storage 406 may include one or more storage control units facilitating communication between processor 402 and storage 406, where appropriate. Where appropriate, storage 406 may include one or more storages 406. Although this disclosure describes and illustrates particular storage, this disclosure contemplates any suitable storage.

In particular embodiments, I/O interface 408 includes hardware, software, or both, providing one or more interfaces for communication between vessel modeling system 400 and one or more I/O devices. Vessel modeling system 400 may include one or more of these I/O devices, where appropriate. One or more of these I/O devices may enable communication between a person and vessel modeling system 400. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 408 for them. Where appropriate, I/O interface 408 may include one or more device or software drivers enabling processor 402 to drive one or more of these I/O devices. I/O interface 408 may include one or more I/O interfaces 408, where appropriate. Although this disclosure describes and illustrates a particular I/O interface, this disclosure contemplates any suitable I/O interface.

In particular embodiments, communication interface 210 includes hardware, software, or both providing one or more interfaces for communication (such as, for example, packet-based communication) between vessel modeling system 400 and one or more other vessel modeling systems 400 or one or more networks. As an example and not by way of limitation, communication interface 210 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 210 for it. As an example and not by way of limitation, vessel modeling system 400 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, vessel modeling system 400 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network, a Long-Term Evolution (LTE) network, or a 5G network), or other suitable wireless network or a combination of two or more of these. Vessel modeling system 400 may include any suitable communication interface 410 for any of these networks, where appropriate. Communication interface 410 may include one or more communication interfaces 410, where appropriate. Although this disclosure describes and illustrates a particular communication interface, this disclosure contemplates any suitable communication interface.

In particular embodiments, bus 412 includes hardware, software, or both coupling components of vessel modeling system 400 to each other. As an example and not by way of limitation, bus 412 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 412 may include one or more buses 412, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific Ics (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

In an embodiment, vessel modeling system 400 may be configured to initiate a process (see FIG. 1) in order to transform a gauging report to a virtual vessel model. In an embodiment, vessel modeling system 400 may be configured to a vessel definition and a gauging report to determine a plurality of virtual vessel data associated with a vessel, such as plate thicknesses, gauging locations, and plate identifiers, etc. In an embodiment, vessel modeling system 400 may be configured to use the plurality of virtual vessel data to generate a virtual model based on a 3D compartment model, a 3D structural model, and/or a finite element model. In an embodiment, vessel modeling system 400 may be configured to use the plurality of virtual vessel data to generate a digital twin based on the virtual model using the plurality of virtual vessel data. In an embodiment, vessel modeling system 400 may be configured to use the digital twin to predict one or more structural responses for the vessel.

Modifications, additions, or omissions may be made to the systems and apparatuses described herein without departing from the scope of the disclosure. The components of the systems and apparatuses may be integrated or separated. Moreover, the operations of the systems and apparatuses may be performed by more, fewer, or other components. Additionally, operations of the systems and apparatuses may be performed using any suitable logic comprising software, hardware, and/or other logic. As used in this document, “each” refers to each member of a set or each member of a subset of a set.

Modifications, additions, or omissions may be made to the methods described herein without departing from the scope of the invention. For example, the steps may be combined, modified, or deleted where appropriate, and additional steps may be added. Additionally, the steps may be performed in any suitable order without departing from the scope of the present disclosure.

Although the present invention has been described with several embodiments, a myriad of changes, variations, alterations, transformations, and modifications may be suggested to one skilled in the art, and it is intended that the present invention encompass such changes, variations, alterations, transformations, and modifications as falling within the scope of the appended claims. Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly provided by the patentee. The indefinite articles “a” or “an,” as used in the claims, are each provided herein to mean one or more than one of the elements that it introduces.

A number of examples have been described. Nevertheless, it may be understood that various modifications can be made. Accordingly, other implementations are within the scope of the following claims.

What is claimed is:

1. A modeling method for a vessel, the method comprising:
providing a vessel definition;
receiving a gauging report comprising a plurality of plate thicknesses of the vessel and sketches showing locations of the plurality of plate thicknesses in a survey;
extracting the plurality of plate thicknesses from the gauging report;
connecting the sketches to one or more of the plate thicknesses;
generating, using a digital twin and a three-dimensional model, a virtual vessel model using the plurality of plate thickness and the sketches;
determining, using the virtual vessel model, a structure response for the vessel; and
determining, using the virtual vessel model and the structural response, a task to apply a remedial operation.

2. The modeling method of claim 1, wherein the vessel definition determines the vessel and a plurality of vessel components, the plurality of vessel components including hull parts based on existing data.

3. The modeling method of claim 2, wherein the existing data includes one or more main structural elements based on classification data and drawings.

4. The modeling method of claim 3, wherein boundaries of the one or more main structural elements form a frame, deck, side shells, or other hull parts for use.

5. The modeling method of claim 4, wherein the boundaries of the one or more main structural elements are determined with or without a three-dimensional (3D) compartment model or a 3D structural model, the 3D compartment model or 3D structural model including a plurality of plate definitions and/or boundaries.

6. The modeling method of claim 1, further comprising:
performing optical character recognition of the survey in the gauging report to extract usable data, the gauging report including a plurality of tables of thicknesses and sketches in portable document format (PDF) files.

7. The modeling method of claim 1, further comprising:
adjusting the vessel definition as the gauging report is read by correlating plate identifiers to plates, compartments and bulkheads definitions.

8. The modeling method of claim 1, further comprising:
applying a supervised or unsupervised machine learning and heuristics including virtual vessel data to connect every measurement with an associated sketch.

9. The modeling method of claim 1, further comprising:
applying one or more image processing and image recognition algorithms to identify the locations of gauge points from the sketches in the survey.

10. The modeling method of claim 1, further comprising:
determining, for each sketch, an origin and a scale using sketch boundaries and a largest linear dimensions from the gauging report; and
determining, for each sketch, a respective scaled sketch by converting the locations from paper scale to vessel scale based on the origin and the scale.

11. The modeling method of claim 10, further comprising:
orienting, for each sketch, the respective scaled sketch based on various identifiers in a corresponding sketch and existing vessel data using heuristic methods.

12. The modeling method of claim 11, further comprising:
applying, for each sketch, one or more correlation techniques to map a point in the scaled sketch to a corresponding location on the vessel using the vessel model.

13. The modeling method of claim 1, further comprising:
determining the structural response to a real-time event by performing physics-based analysis on the one or more plate thicknesses on one or more 3D models.

14. The modeling method of claim 1, further comprising:
determining an error resistant modification of plate thickness based on estimated corrosion rates for plates that are not gauged and determination of such rates from gauged points and their locations on the vessel.

15. The modeling method of claim 14, further comprising:
calculating remaining useful life and estimating corrosion on other vessels by correlating the estimated corrosion rates and historic trends to vessels operation.

16. The modeling method of claim 1, wherein the sketches are computer-aided design (CAD) generated.

17. A modeling method for a vessel, the method comprising:
providing a vessel definition;
receiving a gauging report comprising a plurality of plate thicknesses of the vessel and sketches showing locations of the plurality of plate thicknesses in a survey;
extracting the plurality of plate thicknesses from the gauging report;
connecting the sketches to one or more of the plate thicknesses;
identifying the locations in the vessel definition for the one or more of the plate thicknesses; and
correlating the one or more of the plate thicknesses to a vessel model.

18. A modeling method for a vessel, the method comprising:
providing a vessel definition;
receiving a gauging report comprising a plurality of plate thicknesses associated with several structural members in a survey;
identifying locations in the vessel definition for one or more of the structural members; and
correlating one or more of the plate thicknesses to a vessel model.

19. The modeling method of claim 18, wherein the vessel definition determines a vessel and a plurality of vessel components, the plurality of vessel components including hull parts based on existing data, and the existing data includes one or more main structural elements based on classification data and drawings.

20. The modeling method of claim 19, wherein boundaries of the one or more main structural elements form a frame, deck, side shells, or other hull parts for use, and the boundaries of the one or more main structural elements are determined with or without a three-dimensional (3D) compartment model or a 3D structural model, the 3D compartment model or 3D structural model including a plurality of plate definitions and/or boundaries.
